(19) United States
(12) Patent Application Publication
(10) Pub. No.: US 2009/0268495 A1
(43) Pub. Date: Oct. 29, 2009

(54) Electric circuit, use of a semiconductor component and method for manufacturing a semiconductor component

(76) Inventor: Yohannus Otto Rooymans, Ermelo (NL)

Correspondence Address: HOWREY LLP-EU, C/O IP DOCKETING DEPARTMENT, 2941 FAIRVIEW PARK DR., SUITE 200, FALLS CHURCH, VA, 22042, US

(21) Appl. No.: 11/794,777

(22) PCT Filed: Jan. 4, 2006
(86) PCT No.: PCT/NL06/50002

§ 371 Date: Jul. 5, 2007

(30) Foreign Application Priority Data
Jan. 5, 2005 (NL) 1027961

(51) Int. Cl. H02M 7/06; H01L 21/20

(52) U.S. Cl. 363/126; 438/478; 257/E21.09

(57) ABSTRACT

The invention relates to an electric circuit comprising at least one semiconductor component (38, 39, 40). The semiconductor component has a first area (52) of a first conduction type that is adjacent to a second area (53a) of a second conduction type. A first diode (4, 5, 8) is formed in this way. The first area (52) is also adjacent to a third area (53b) that is also of the second conduction type, with the result that the first and third areas form a second diode (6, 7, 9). When in operation, the circuit is designed such that both the first diode (4, 5, 8) and the second diode (6, 7, 9) only conduct current in a forward direction.

The invention relates to an electric circuit comprising at least one semiconductor component. A circuit for which the present invention is suitable is described in an application submitted in parallel by the same applicant (Dutch Patent Application 1027960). This application discloses, inter alia, a bridge circuit which is arranged such that at least four rectifiers, preferably diodes, conduct a rectified current through at least one lighting element. Producing such a bridge circuit with individual diode components in chips is a time-consuming task because the chips have to be positioned with the correct orientation by a positioning device, whereas they are supplied with the same orientation in current techniques. The process to connect all the components is also complex. This complexity results in long connections between the components. As a result of the long connections, extra energy loss occurs and unnecessary heat is generated.

The invention is also intended to provide a more efficient circuit in which the length of the connections can be reduced and the efficiency of a positioning machine for positioning electric components in a circuit also can be improved. This aim is achieved by the electric circuit according to the invention by means of an electric component wherein the electric circuit comprises at least one semiconductor component that comprises a first area of a first conduction type, which first area is adjacent to a second area of a second conduction type and thus forms a first diode, and which first area is also adjacent to a third area that is also of the second conduction type, with the result that the first and third areas form a second diode, wherein the circuit when in operation is designed such that both the first diode and the second diode only conduct current in a forward direction. The present invention provides a means of ensuring that only one semiconductor component has to be incorporated in the circuit instead of two different diodes.

In an embodiment the first conduction type is an n-type conductor, i.e. conductance by means of electrons, and the second conduction type is a p-type conductor, i.e. conductance by means of holes. In another embodiment these conduction types are reversed.

In an embodiment, at least one of the first diode and the second diode is a light-emitting diode (LED). In many circuits it is possible for one single component to achieve the light output of two separate LEDs in this way.

The semiconductor component in the circuit preferably has a first contact surface with the first area, a second contact surface with the second area and a third contact surface with the third area. The presence of the contact surfaces simplifies assembly in an electronic circuit. The contact surfaces are preferably positioned in one two-dimensional plane, such as used in so-called flip-chip technology. This enables the contact surfaces to be bonded easily to a solid substrate, for example a printed circuit board. Furthermore, the contact surfaces are preferably connected to a medium which promotes heat dissipation, for example a conductive layer, more preferentially a metal layer made of copper (Cu) which is located on a ceramic substrate. This enables any loss of performance by the component when in use to be minimised. The ceramic substrate provides the necessary rigidity. Ceramic is particularly suitable because of its low coefficient of thermal expansion, as a result of which mechanical stresses in response to temperature fluctuations are kept to a minimum.

For protective purposes, the electric component is preferably covered with a protective cap. If the electric component comprises a light-emitting diode, the protective cap is practically transparent to a wavelength that is emitted by the light-emitting diode in operation.

The invention also relates to the use of a semiconductor component for rectifying electric current, wherein the semiconductor component comprises a first area of a first conduction type, which first area is adjacent to a second area of a second conduction type and thus forms a first diode, and which first area is also adjacent to a third area that is also of the second conduction type, with the result that the first and third areas form a second diode, wherein both the first diode and the second diode only conduct current in a forward direction when in operation.

In one embodiment the first conduction type is an n-type conductor, i.e. conductance by means of electrons, and the second conduction type is a p-type conductor, i.e. conductance by means of holes. In another embodiment these conduction types are reversed.

The advantages of such operation correspond to the aforementioned advantages of such a semiconductor component in an electric circuit.

The invention further relates to a method for manufacturing a semiconductor component for rectifying electric current, comprising:
providing a first substrate made of n-material;
applying a layer of p-material to the first substrate;
selectively removing p-material in accordance with a first pattern until part of the first substrate is exposed and first and second insulated areas of p-material have been formed at least by means of grooves;
selectively applying a first conductive layer in accordance with a second pattern in order thus to make a first connection to the first substrate, a second connection to the first area of p-material and a third connection to the second area of p-material;
attaching the first substrate to a second substrate of an insulating material.

In identical fashion, the invention relates to a method for manufacturing a semiconductor component for rectifying electric current, comprising:
providing a first substrate made of p-material;
applying a layer of n-material to the first substrate;
selectively removing n-material in accordance with a first pattern until part of the first substrate is exposed and first and second insulated areas of n-material have been formed at least by means of grooves;
selectively applying a first conductive layer in accordance with a second pattern in order thus to make a first connection to the first substrate, a second connection to the first area of n-material and a third connection to the second area of n-material;
attaching the first substrate to a second substrate (60) of an insulating material.

In both methods the second substrate is preferably provided with a second conductive layer in accordance with a third pattern on a side which is attached to the first substrate. The second conductive layer can promote heat dissipation and is, for example, a layer of copper.

The second substrate is made of, for example, ceramic. An important advantage of this material is that it has a low coefficient of thermal expansion, as a result of which mechanical stresses in the electric component as a result of temperature fluctuations are minimised.

The at least one first conductive layer preferably comprises a chromium (Cr) layer, a molybdenum (Mo) layer and a silver (Ag) layer. Chromium ensures good reflection of any light generated at a pn-transition, while molybdenum enhances the rigidity of the at least one first conductive layer. Both materials have a coefficient of thermal expansion which is almost equal to the coefficient of thermal expansion of the n-material and the p-material. Consequently, the occurrence of mechanical stresses between the layers as a result of temperature fluctuations is kept to a minimum. Silver, finally, is a good conductor that is simple to bond.

The connection of the first substrate to the second substrate is preferably carried out by means of soldering with a solder comprising gold and tin. Such a combination is very suitable for connecting such substrates, because this alloy has a sufficiently high eutectic melting point, as a result of which the substrate connection does not break down as a result of self-heating during operation.

The method preferably includes the covering of the first substrate with a domed protective cap down to the second substrate. Said protective cap protects the electric component against external influences.

The invention will now be further explained below by way of example with reference to the following figures. The figures are not intended to restrict the scope of the invention, but merely to illustrate it.

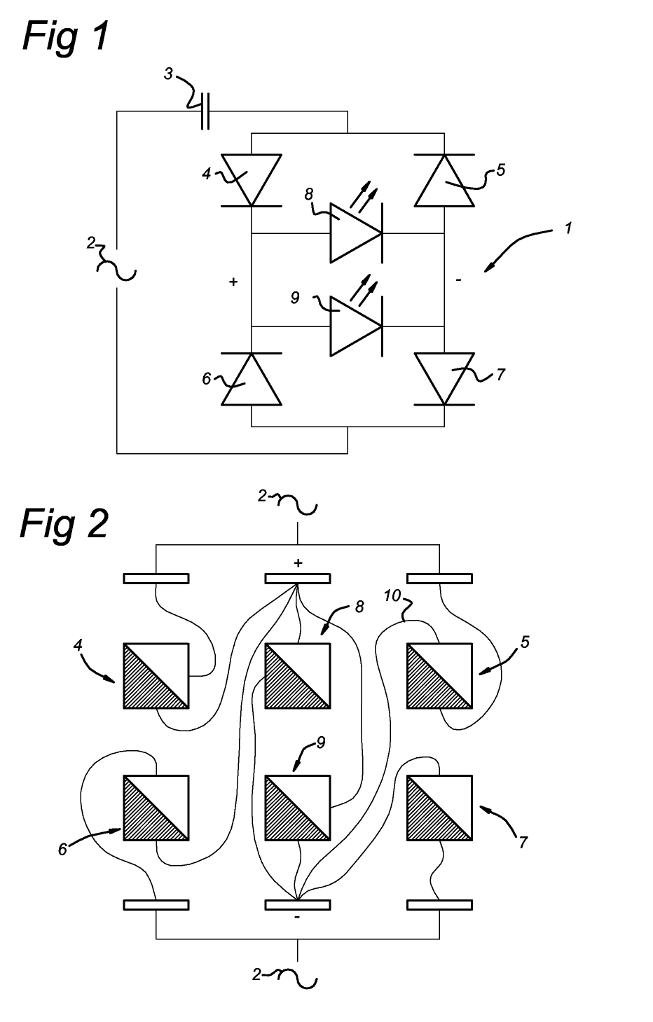

FIG. 1 is a schematic representation of a circuit with a diode bridge circuit;

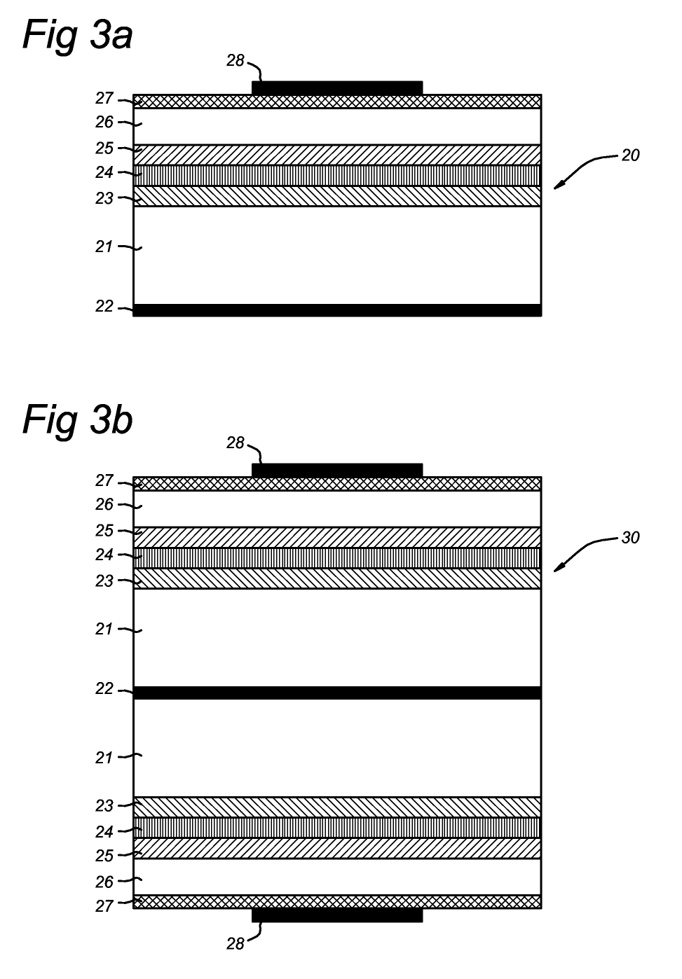

FIG. 2 is a schematic representation of a bonding scheme for the bridge circuit shown in FIG. 1;

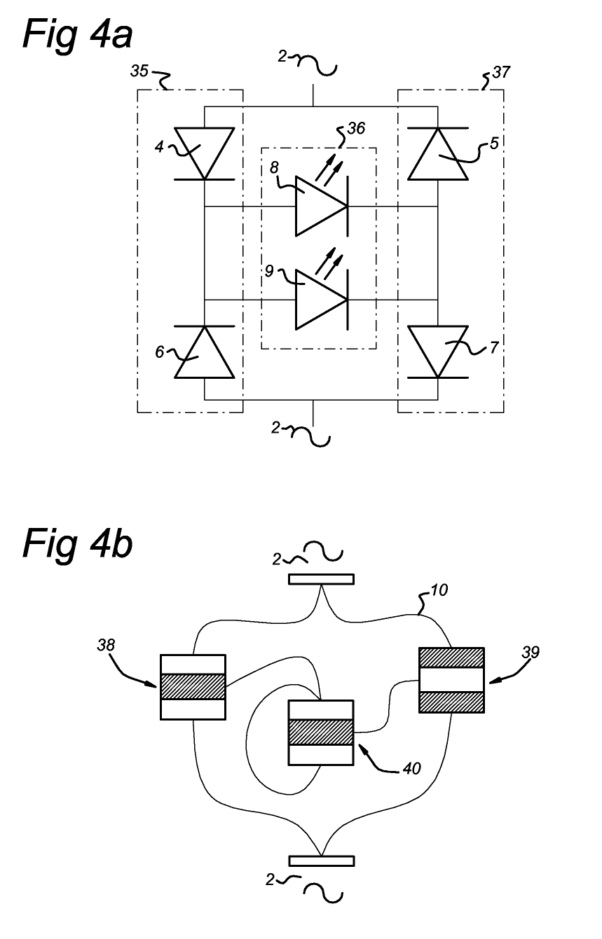

FIG. 3a is a schematic representation of a pn diode;

FIG. 3b is a schematic representation of a pnp diode, corresponding to a first embodiment of the invention;

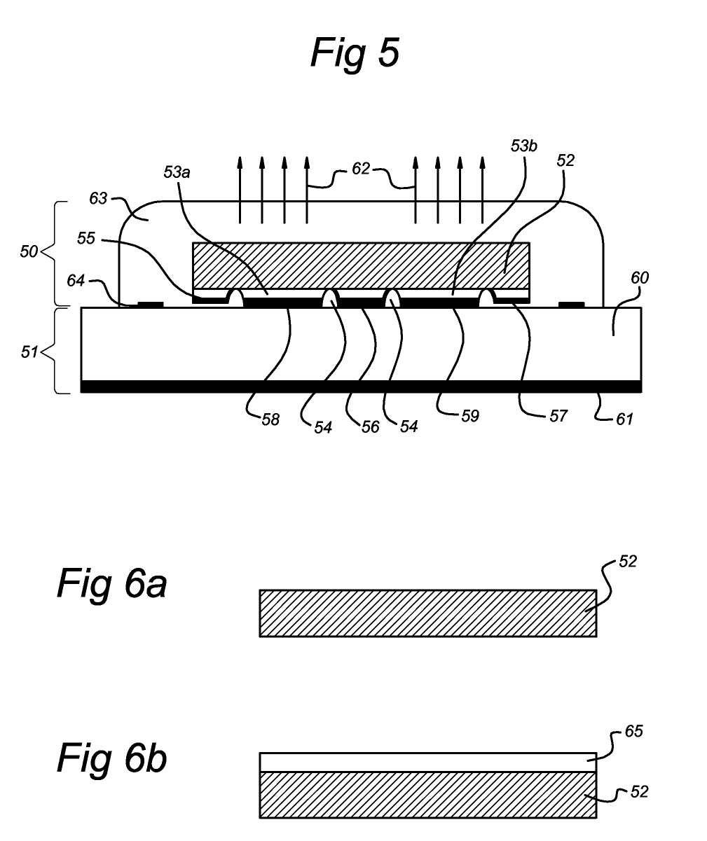

FIG. 4a is a schematic representation of an option for implementing the present invention in the circuit shown in FIG. 1;

FIG. 4b is a schematic representation of a bonding scheme, corresponding to an embodiment of the invention as shown in FIG. 4a;

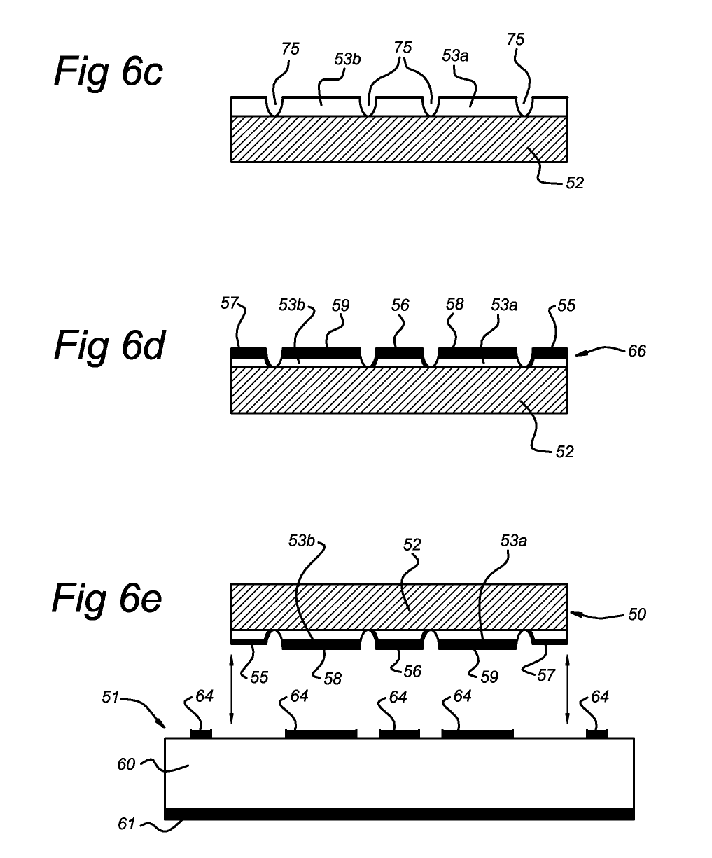

FIG. 5 is a schematic representation of a cross-section of an npn diode including a housing, corresponding to a second embodiment of the invention;

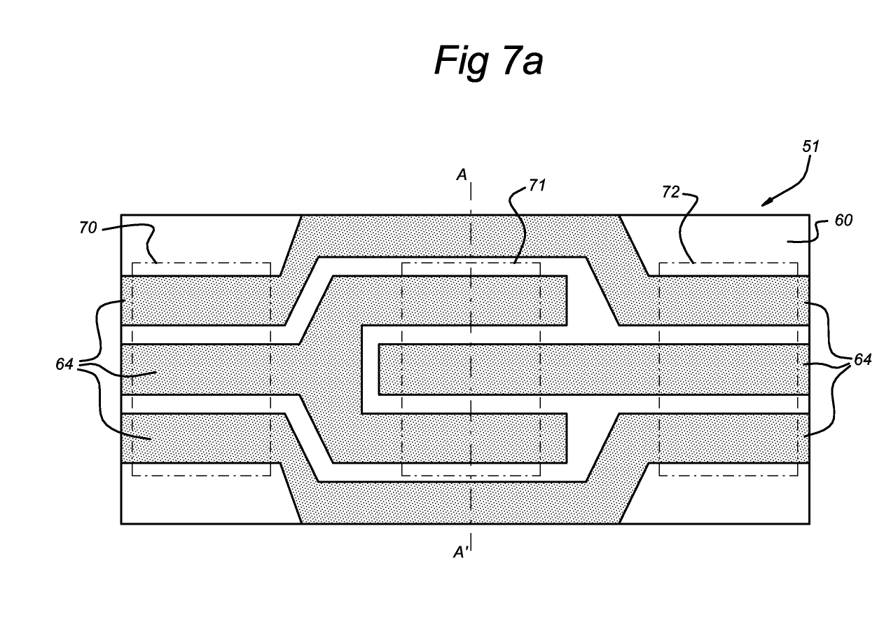

FIGS. 6a-f are schematic representations of a method for manufacturing the npn diode shown in FIG. 5;

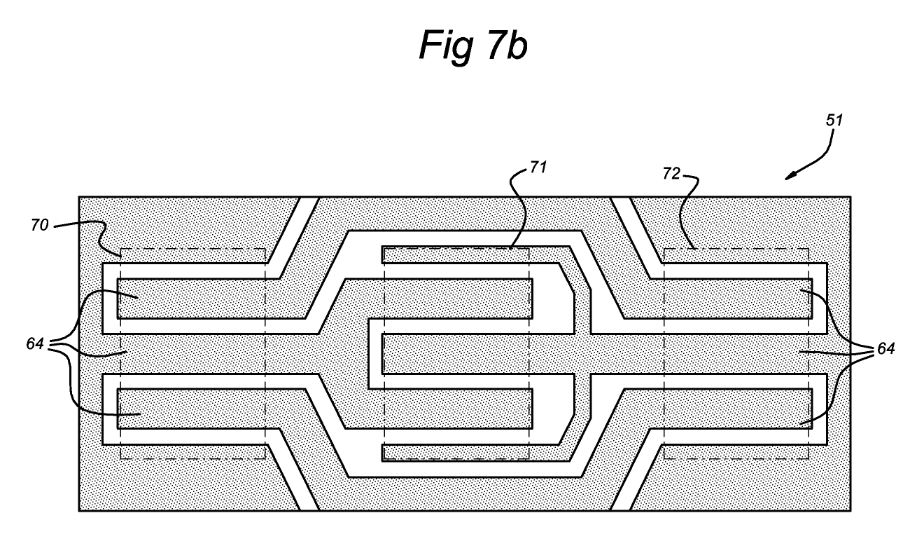

FIG. 7a is a schematic representation of a plan view of a first housing for the circuit with connections as shown in FIG. 4b;

FIG. 7b is a schematic representation of a plan view of a second housing for the circuit with connections as shown in FIG. 4b.

FIG. 1 is a schematic representation of a circuit with a diode bridge circuit 1. In the circuit an alternating current network 2 is connected to a capacitor 3. The diode bridge circuit 1 is connected in series with the capacitor 3. The diode bridge circuit 1 in FIG. 1 comprises four diodes 4, 5, 6, 7 which provide two-phase rectification of the current through two central diodes 8, 9, which in this case are light-emitting diodes (LEDs). Because the LEDs 8, 9 are subject to a forward-biased loading for both phases of the alternating current, the light emitted by LEDs 8, 9 will exhibit an almost constant intensity. It is also possible for one or more of diodes 4, 5, 6, 7 to be LEDs. In addition, each individual diode 4, 5, 6, 7 can be replaced by more than one series-connected diodes.

A circuit as shown in FIG. 1 can be manufactured by positioning separate diodes on a substrate. Because diodes in chip versions are normally fed to a positioning device on a reel, in other words on a long adhesive strip, with a fixed orientation, the positioning device generally first has to turn the diodes before they can be positioned on the substrate. This additional action costs a great deal of time. Consequently, the productivity of the positioning device is reduced. Furthermore, the process of connecting all the electrical components in a circuit is complex, in part because contact between the bondings must be avoided. This complexity often results in long bondings between the various electrical components. As a consequence of the long bondings, there is a relatively large energy loss and extra heat is unnecessarily generated.

FIG. 2 is a schematic representation of a bonding scheme for the bridge circuit shown in FIG. 1. All the diodes 4-9 comprise a p-section, a section with a deficiency of electrons, and an n-section, a section with an excess of electrons. Examples of suitable elements for the p-section are gallium (Ga), indium (In), indium-gallium nitride (InGaN) and aluminium (Al). Examples of suitable elements for the n-section are phosphorus (P) and arsenic (As). The transition between a p-section and an n-section, termed a pn-junction, can operate as a rectifier. The p-sections of the diodes 4-9 are represented by the white triangles. The n-sections of the diodes 4-9 are represented by the diagonally hatched triangles. The bondings 10 shown form electrical connections and correspond to the connections as shown schematically in FIG. 1. It is clearly apparent that the creation of such bondings 10 is a complex process. It is therefore desirable to restrict the number of bondings 10 and not to make them too long, in order to limit energy losses.

FIG. 3a is a schematic representation of a more detailed composition of a pn diode 20, in this case with a base substrate 21 made of n-material, which transmits light in operation if suitable materials are selected. A layer of conductive material 22 is applied to one side of the base substrate. Said conductive material can be connected to an electric circuit in order to function as an n-electrode. At the other side are present an n-cladding layer 23, an active layer 24 and a p-cladding layer 25 in that order. The cladding layers 23, 25 are layers which comprise a number of layers with different optical retraction indices. They are applied to achieve optimum optical radiation of the generated light in the desired direction. A layer 26 which is suitable for current diffusion is then applied to this, a passivation layer 27 follows on top of this to protect the structure and finally a conductive layer 28 that can be connected to an electric circuit is applied to this in turn, in this case to function as a p-electrode. In the case of a pn diode with a base substrate 22 made of p-material, the structure of the diode does not change, the order of the cladding layers 23 and 25 is reversed and the functions of the p-electrode and the n-electrode also change place, of course.

FIG. 3b is a schematic representation of a pnp diode 30 according to a first embodiment of the invention. The structure of this diode 30 is, in fact, a diode 20 which is constructed in two opposing directions from the conductive layer 21, which functions as an n-electrode, until a conductive layer 28, which functions as a p-electrode, is reached on both sides. It is a straightforward matter to understand that an npn diode can be obtained in identical fashion.

FIG. 4a is a schematic representation of an option of implementing the present invention in the circuit shown in FIG. 1. The rectangles 35, 36, 37 indicated by broken lines each group together two diodes which could be replaced by a structure as shown in FIG. 3b. Diodes 4, 6 can be replaced jointly by a pnp diode 38. Diodes 5, 7 can for their part be replaced jointly by an npn diode 39. It is even possible to merge the function of LEDs 8, 9 into, for example, a pnp diode 40. The replacement elements 38, 39, 40 are shown in FIG. 4b, which is a schematic representation of a bonding scheme of the circuit shown in FIG. 4a. The p-sections in the replacement elements 38, 39, 40 are indicated by the blank rectangles, while the n-sections are represented by diagonally hatched rectangles. Compared with the bonding scheme of FIG. 2, not only is the number of components to be bonded halved, but there is also a reduction in the number of bondings from 13 to 7. If a positioning machine uses two reels, one provided with npn diodes and one provided with pnp diodes, it is also unnecessary to position the replacement elements 38,39, 40 in different orientations, which increases the efficiency of the positioning device.

FIG. 5 is a schematic representation of a cross-section of a semiconductor component that comprises a pnp diode 50 and a support 51 corresponding to a second embodiment of the invention. A method for manufacturing this semiconductor component will be described with reference to FIGS. 6a-6e. The pnp diode comprises a base substrate 52 made of n-material, under which are two areas 53a, 53b of p-material, which areas are separated from one another by openings 54. The connections to the circuit in this embodiment lie in one two-dimensional plane. The base substrate 52 and two areas 53a, 53b made of p-material are connected at suitable locations to different conductive layers 55-57 and 58-59, respectively, all of which are shown in black in the figure. Contacts 55, 56 and 57 are connected to the base substrate 52 made of n-material. They therefore have the function of an n-electrode. Contacts 58 and 59 make contact with two separate areas 53a, 53b made of p-material and are therefore used as two p-electrodes in the circuit. Just as in previously discussed configurations, an equivalent structure is possible for an npn diode. The base substrate 52 is then made of p-material and the two areas 53a, 53b in that case are provided with n-material.

The support 51 comprises of a substrate 60 made of insulating material, which on one side facing the pnp diode 50 is equipped to provide an external contact for the contacts 55-59, for example via electrically conductive tracks 64. In FIG. 5, however, contacts 55 and 57 are not connected to a conductive track 64. Furthermore, the insulating substrate can, as shown in FIG. 5, can be provided with a conductive layer 61 that consists of, for example, a copper layer (Cu) on an opposite side. As a result of the presence of conductive material on both sides of the insulating substrate 60, support 51 forms a capacitance in the semiconductor component, which can be used, for example, as a capacitor 3 in the circuit shown in FIG. 1. The substrate 60 is preferably made from a material with a low coefficient of thermal expansion, such as ceramic.

In operation, if the voltage is sufficient, an electric current will flow from the areas 53a, 53b made of p-material to the base substrate 52 made of n-material. If the diode 50 is a LED, the diode 50 will emit light at the pn-junction, as indicated by means of arrows 62 in FIG. 5. The wavelength of the light depends on the composition of the n-material and the p-material used. The contacts 55-58 preferably cover a large surface area if they comprise materials with a good reflective effect. A large reflective surface area enables the generated light to be directed in the desired direction, in the case of diode 50 in the direction indicated by the arrows 62.

The entire diode 50 can be covered with a protective cap 63 for protection purposes. In the case of a LED, the protective cap 63 is preferably made of a material that is practically transparent to the wavelength of the light emitted by the LED.

FIGS. 6a-e are schematic representations of a method for manufacturing a structure comprising a pnp diode 50 and support 51, as shown in FIG. 5. The first step is to provide a base substrate 52 made of n-material, as shown in FIG. 6a. A layer 65 of p-material is applied to this base substrate 52 using techniques that are known in the state of the art (FIG. 6b). In order to make the resulting structure almost flat, the applied layer 65 of p-material can be lapped. Then p-material is then selectively removed from this layer 65 of p-material, for example by means of etching a pattern with the aid of a mask, until a desired surface of the base substrate 52 is exposed (FIG. 6c). By selectively removing p-material, grooves 75 are produced which extend to the base substrate 52 and thus at least two mutually insulated areas 53a, 53b made of p-material are formed. A suitable conductive layer 66 is then selectively applied (FIG. 6d), for example with the aid of shadow masks, whereby it is important that no conductive connection is produced between the at least two insulated areas 53a, 53b made of p-material and the base substrate 52 made of n-material. Contacts 55-59, as shown in FIG. 5, are formed in this way. In FIG. 6d both the at least two insulated areas 53a, 53b made of p-material and the grooves 75 are covered with the same conductive layer 66. It is, however, also possible for different types of conductive material to be applied at different locations. A plurality of conductive layers 66 can also be applied on top of one another. For instance, it is, for example, possible to apply successively a chromium (Cr) layer, a molybdenum (Mo) layer and a silver (Ag) layer. If necessary, for example as a result of the presence of a short-circuit via conductive layer 66 between the at least two mutually insulated areas 53a, 53b and/or the base substrate 52, the conductive layer 66 can be selectively removed using known techniques, such as etching. The conductive layer 66 can serve as a p-electrode or as an n-electrode, depending on the location.

In an embodiment of the invention which is not shown, the contacts 55 and 57 axe formed by removing the entire p-layer 65 at these locations, for example by making use of additional masks, and then providing conductive material on the base substrate 52 made of n-material, separated from the at least two mutually insulated areas 53a, 53b, to a depth almost identical to that of these areas 53a, 53b. The resulting contact points 55, 57 will, if connected to an electric circuit, contribute in operation to a uniform, distribution of electric current in the base substrate 52 made of n-material, as a result of which the light output at the pn-transitions is more uniformly distributed between the base substrate 52 and the insulated areas 53a, 53b.

In order now to obtain the structure as shown in FIG. 5, a second substrate 60 made of insulating material is provided. This second substrate 60 is shown in FIG. 6e in a comparison with the opposite structure of FIG. 6d. Electric tracks 64, which together form a pattern that is suitable for enabling the desired connections between contacts 55-59 and external contacts for use in a circuit, are preferably applied to one side on the second substrate 60. In many cases the pattern formed almost corresponds to the pattern used in the selective removal of p-material (FIG. 6c). This pattern can be produced using techniques known in the state of the art. The surface area of the conductive tracks 64 at the locations of the support 51 where a connection occurs with the pnp diode 50 is preferably smaller than the relevant contact 55-59 on the pnp diode 50. This has the advantage that the chance of a short-circuit between the contacts 55-59 can be minimised when affixing by means of, for example, soldering. The other side of the substrate 60 can be covered with a conductive layer 61, for example copper (Cu), the primary function of which is to dissipate heat. The second substrate 60 including the conductive layer 61 can also serve as a capacitor, for example as capacitor 3 in the circuit as shown in FIG. 1. The second substrate 60 is preferably made of a material with a low coefficient of thermal expansion, for example ceramic. The connection between the resulting pnp diode and the second substrate 60 is made using known techniques, for example by means of soldering an Au—Sn soldered connection at a suitable temperature, for example approximately 278° C. Finally, the whole structure can also be covered with a protective cap 63.

If so desired, various other layers can, of course, be applied between the base substrate 52 and the at least two insulated areas 53a, 53b of p-material. Examples are one or more cladding layers and/or active layers, as shown in FIGS. 3a-b.

FIG. 7a is a schematic representation of a plan view of the support 51 comprising a second substrate 60 which is provided with a first pattern of electrically conductive tracks 64 suitable for using the invention in the circuit shown in FIG. 4b. The line A-A′ corresponds to the cross-section of the support 51 as shown in FIG. 6e. The electrically conductive tracks 64 are shown stippled and the surrounding substrate 60 non-stippled. The rectangles 70, 71, 72 shown here indicate where a semiconductor component according to the invention can be positioned. The circuit as shown in FIG. 4b can be obtained by positioning a pnp diode corresponding to diode 38 in rectangle 70, a pnp diode corresponding to diode 40 in rectangle 71 and an npn diode corresponding to diode 39 in rectangle 72, where the pnp diode in rectangle 71 can be a pnp diode 50, as shown in FIG. 6e. The outermost contacts 55 and 57 of this pnp diode 50, just as in FIG. 6e, make no contact with one of the electrically conductive tracks 64.

With the aid of such a support 51 comprising a substrate 60 which is provided with a suitable pattern, it is possible to produce in a simple manner a complex circuit without any bonding. Moreover, using the electrical components according to the invention means that fewer components than usual are required for this type of circuit.

The contacts 55 and 57 of pnp diode 50 can perform a function as an additional electrical connection, for example with the aid of a conductive compound that comprises, for example, silver (Ag). If the connection concerns a connection to contact 56, better current distribution at the light-generating transitions between base substrate 52 and areas of p-material 53a and 53b can be achieved. Such an additional connection will in many cases result in a more complex pattern of electric tracks 64, as can be seen in FIG. 7b, which is a schematic representation of a plan view of a second embodiment of the support 51 that comprises a second substrate 60 which is provided with a second pattern of electrically conductive tracks 64 suitable for using the invention in the circuit shown in FIG. 4b.

The above description only sets out a number of possible embodiments of the present invention. It is clear that many alternative embodiments of the invention are conceivable, all of which fall within the scope of the invention. This is defined by the following claims.

1. Electric circuit comprising at least one semiconductor component (38, 39, 40) that comprises a first area (52) of a first conduction type, which first area (52) is adjacent to a second area (53a) of a second conduction type and thus forms a first diode (4, 5, 8), and which first area is also adjacent to a third area (53b) that is also of the second conduction type, with the result that the first and third areas form a second diode (6, 7, 9), wherein the circuit when in operation is designed such that both the first diode (4, 5, 8) and the second diode (6, 7, 9) only conduct current in a forward direction.

2. Electric circuit according to claim 1, characterised in that the first conduction type is an n-type conduction and the second conduction type is a p-type conduction.

3. Electric circuit according to claim 1, characterised in that the first conduction type is a p-type conduction and the second conduction type is an n-type conduction.

4. Electric circuit according to one of the preceding claims, characterised in that at least one of the first diode (4, 5, 8) and the second diode (6, 7, 9) is a light-emitting diode (LED).

5. Electric circuit according to one of the preceding claims, characterised in that the semiconductor component has a first contact surface (22, 55, 77) with the first area (52), a second contact surface (28, 58) with the second area (53a) and a third contact surface (28, 59) with the third area (53b).

6. Electric circuit according to claim 5, characterised in that the first, second and third contact surfaces (55-59) are positioned in one two-dimensional plane.

7. Electric circuit according to claim 6, characterised in that the first, second and third contact surfaces (55-59) are connected to a medium which promotes heat dissipation.

8. Electric circuit according to claim 7, characterised in that the medium which promotes heat dissipation is a conductive layer (61) located on a substrate (60) made of ceramic.

9. Electric circuit according to claim 8, characterised in that the conductive layer (61) is a metal layer made of copper (Cu).

10. Electric circuit according to one of the preceding claims, characterised in that the semiconductor component is covered with a protective cap (63).

11. Electric circuit according to claim 10, characterised in that at least one of the first diode (4, 5, 8) and the second diode (6, 7, 9) is a light-emitting diode (LED) and the protective cap (63) is practically transparent to a wavelength that is emitted by the LED in operation.

12. Use of a semiconductor component for rectifying electric current, wherein said semiconductor component comprises a first area (52) of a first conduction type, which first area (52) is adjacent to a second area (53a) of a second conduction type and thus forms a first diode (4, 5, 8), and which first area is also adjacent to a third area (53b) that is also of the second conduction type, with the result that the first and third areas form a second diode (6, 7, 9), wherein both the first diode (4, 5, 8) and the second diode (6, 7, 9) only conduct current in a forward direction when in operation.

13. Use of a semiconductor component according to claim 12, characterised in that the first conduction type is an n-type conduction and the second conduction type is a p-type conduction.

14. Use of a semiconductor component according to claim 12, characterised in that the first conduction type is a p-type conduction and the second conduction type is an n-type conduction.

15. Method for making a semiconductor component for rectifying electric current, comprising:
providing a first substrate (52) made of n-material;
applying a layer of p-material (65) to the first substrate;
selectively removing p-material in accordance with a first pattern until part of the first substrate (52) is exposed and first (53a) and second (53b) insulated areas of p-material have been formed at least by means of grooves (75);
selectively applying at least one first conductive layer (66) in accordance with a second pattern in order thus to make a first connection to the first substrate (52), a second connection to the first area (53a) of p-material and a third connection to the second area (53b) of p-material;
attaching the first substrate (52) to a second substrate (60) of an insulating material.

16. Method for manufacturing a semiconductor component for rectifying electric current, comprising:
providing a first substrate (52) made of p-material;
applying a layer of n-material (65) to the first substrate;
selectively removing n-material in accordance with a first pattern until part of the first substrate is exposed and first (53a) and second (53b) insulated areas (53) of n-material have been formed at least by means of grooves (75);
selectively applying at least one first conductive layer (66) in accordance with a second pattern in order thus to make a first connection to the first substrate (52), a second connection to the first area (53a) of n-material and a third connection to the second area (53b) of n-material;
attaching the first substrate (52) to a second substrate (60) of an insulating material.

17. Method according to claim 15 or 16, characterised in that the second substrate (60) is provided with a second conductive layer (61) in accordance with a third pattern on one side which is attached to the first substrate (50).

18. Method according to claim 17, characterised in that the second conductive layer (61) is a layer of copper (Cu).

19. Method according to one of claims 15-18, characterised in that the second substrate (60) is a substrate made of ceramic.

20. Method according to one of claims 15-19, characterised in that the at least one first conductive layer (66) comprises a chromium (Cr) layer, a molybdenum (Mo) layer and a silver (Ag) layer.

21. Method according to one of claims 15-20, characterised in that attaching the first substrate (52) to the second substrate (60) is carried out by means of soldering with a solder comprising gold (Au) and tin (Sn).

22. Method according to one of claims 15-21, characterised in that the method, after connection, also includes the covering of the first substrate (52) with a domed protective cap (63) down to the second substrate (60).
